(19) United States
(12) Patent Application Publication
(10) Pub. No.: US 2005/0034660 A1
(43) Pub. Date: Feb. 17, 2005

(54) Alignment means for chamber closure to reduce wear on surfaces

(75) Inventor: Joseph Hillman, Scottsdale, AZ (US)

Correspondence Address: HAVERSTOCK & OWENS LLP, 162 NORTH WOLFE ROAD, SUNNYVALE, CA, 94086, US

(73) Assignee: Supercritical Systems, Inc.

(21) Appl. No.: 10/639,077

(22) Filed: Aug. 11, 2003

(51) Int. Cl. C23C 16/00

(52) U.S. Cl. 118/715

(57) ABSTRACT

An apparatus for closing a chamber, the chamber having a first chamber housing and a second chamber housing, is disclosed. The apparatus comprises a means for forming a chamber including a means for bringing the first chamber housing into contact with the second chamber housing; and a deforming means for preventing formation of particles while the first chamber housing contacts the second chamber housing, wherein the deforming means is mounted on at least one of the first chamber housing and the second chamber housing such that it deforms to accommodate any misalignment while the means for forming a chamber operates.

### FIELD OF THE INVENTION

The present invention in general relates to the field of cleaning semiconductor wafers. More particularly, this invention relates to apparatus and methods to enhance alignment to thereby reduce or eliminate the formation of particles from wear on surfaces of parts that come into contact with each other during semiconductor wafer processing and where some relative motion can otherwise occur between the contacting surfaces.

### BACKGROUND OF THE INVENTION

It is well known that particulate surface contamination of semiconductor wafers typically degrades device performance and affects yield in the industry. When processing wafers, it is desirable that particles and contaminants such as photoresist, photoresist residue, and residual etching reactants and byproducts be minimized.

Use of chambers for processing semiconductor wafers is known. Where some relative motion occurs between the surfaces of parts that come into contact with each other during processing, there can be wear on the surfaces and the undesired increases in particles associated with it. In this document, “wear” is a broad term that encompasses many types of failures, all of which involve changes to at least a portion of the surface of the part. Commonly known categories of wear include adhesive wear, abrasive wear, erosion, corrosion wear and surface fatigue. Some of these wear mechanisms are not completely understood, and rival theories exist in some cases. It is possible that more than a single mechanism occur at the same time. In addition, there are types of surface failure that do not fit neatly into one of the above-identified categories or that can fit into more than one. For example, “fretting corrosion” has aspects of both corrosion wear and surface fatigue. Other types of surface failure that can potentially impact the effectiveness of supercritical processing include “fretting” and “galling.”

As discussed in both, U.S. Pat. No. 5,292,596 to Privett, III, et al., entitled “Force-Transmitting Surfaces of Titanium Protected from Fretting Fatigue By a Coating of CO—NI—FE,” issued Mar. 8, 1994, and U.S. Pat. No. 5,312,696 to Beers, et al., entitled “Method for Reducing Fretting Wear Between Contacting Surfaces,” issued May 17, 1994, fretting (also referred to as “fretting wear”) occurs on force-transmitting surfaces of parts that contact each other, and which, through transmitted forces such as vibration, oscillate relative to each other with a high frequency, low amplitude motion. Specifically, this phenomenon occurs in assemblies wherein a force-transmitting surface is in rotating, sliding or oscillating contact with a second surface. Since the surfaces may contain many microscopic asperities in contact, the fretting motion tends to cause local adhesion at these contact points, which may fracture, producing material transfer, wear debris, or both.

Prior art efforts to overcome the onset of wear have included providing wear resistant coatings on the surfaces of the materials in contact. For example, conventional methods of minimizing fretting wear include the use of thermal sprayed coatings, solid film lubricants (also known as “dry film lubricants” or “bonded film lubricants”) and coatings of metallic alloys, such as copper-nickel, copper-nickel-indium, or silver plating. While such techniques prevent catastrophic wear to the contacting surfaces they do not eliminate the formation of particles. Particles typically cause damage to an integrated circuit.

The formation of particles from wear on surfaces during supercritical processing of semiconductor wafers has a tendency to increase the difficulty in the effective and efficient removal of contaminants from the semiconductor device feature surfaces and can damage circuits which reduces yield. It would be advantageous to eliminate or minimize the occurrence of fretting, fretting corrosion, galling, adhesive wear, abrasive wear, corrosion wear, surface fatigue, and the like during processing of semiconductor wafers, including supercritical processing of semiconductor wafers.

What is needed is an effective means to reduce or eliminate the formation of particles due to wear on surfaces of parts that come into contact with each other during semiconductor wafer processing.

### SUMMARY OF THE INVENTION

A first embodiment of the invention is for an apparatus for closing a chamber, the chamber having a first chamber housing and a second chamber housing, comprising: means for forming a chamber including means for bringing the first chamber housing into contact with the second chamber housing; and deforming means for preventing formation of particles while the first chamber housing contacts the second chamber housing, wherein the deforming means is mounted on at least one of the first chamber housing and the second chamber housing such that it deforms to accommodate any misalignment while the means for forming a chamber operates.

A second embodiment of the invention is for a method of closing a chamber, the chamber having a first chamber housing and a second chamber housing, comprising the steps of: forming a chamber including bringing the first chamber housing into contact with the second chamber housing; and preventing formation of particles while the first chamber housing contacts the second chamber housing.

A third embodiment of the invention is for a method of eliminating particle generation at a platen/injection ring interface, comprising the steps of: forming a platen/injection ring interface including bringing a platen into contact with an injection ring; and positioning a material on at least one of the injection ring and the platen such that the material deforms to accommodate any misalignment while forming the platen/injection ring interface.

### BRIEF DESCRIPTION OF THE DRAWINGS

The present invention may be better understood by reference to the detailed description and claims when considered in connection with the accompanying drawings, of which:

FIGS. 1A to 1E are schematic illustrations of an apparatus for closing a chamber, including deforming means and showing a cavity in the first chamber housing, in accordance with embodiments of the present invention.

FIGS. 2A to 2E are schematic illustrations of alternative embodiments of an apparatus for closing a chamber, showing various combinations of the deforming means separately shown in FIGS. 1A to 1E.

FIGS. 3A to 3B are schematic illustrations of an apparatus for closing a chamber, including various configurations of deforming means and showing a cavity in the second chamber housing, in accordance with embodiments of the present invention.

FIG. 4 is a schematic illustration of an apparatus for closing a chamber, including deforming means and showing an alignment means, in accordance with one embodiment of the present invention.

FIGS. 5A to 5D are schematic illustrations of an apparatus for closing a chamber, including an alignment means and showing various configurations of deforming means, in accordance with embodiments of the present invention.

FIG. 6 is a schematic illustration of an apparatus for closing a chamber, including deforming means and an alternative alignment means, in accordance with one embodiment of the present invention.

FIG. 7 is a schematic illustration of an apparatus for closing a chamber, including alignment means and deforming means and a cavity in the second chamber housing, in accordance with one embodiment of the present invention.

FIG. 8 is a schematic illustration of one embodiment of an apparatus for closing a chamber, including deforming means and a cavity in the second chamber housing, showing an alternative alignment means.

FIG. 9 is a flow chart showing a method of closing a chamber in accordance with embodiments of the present invention.

FIG. 10 is a flow chart showing a method of a method of eliminating particle generation at a platen/injection ring interface in accordance with embodiments of the present invention.

In the drawings, like reference numbers are used when describing the same elements. Additionally, the left-most digit(s) of a reference number typically identifies the drawings in which the reference number first appears.

### DETAILED DESCRIPTION OF THE PREFERRED EMBODIMENTS

The present invention is directed to an apparatus and method of closing a chamber, the chamber having a first chamber housing and a second chamber housing. In certain embodiments of the invention, the first chamber housing and/or the second chamber housing include a manifold having thereon a plurality of fluid outlets for distributing a process fluid. It will be apparent that there can also be more than just two housing elements that are joined together to form a chamber pursuant to the teachings of the present invention. For the purposes of the invention, “fluid” means a gaseous, liquid, supercritical and/or near-supercritical fluid. In certain embodiments of the invention, “fluid” means gaseous, liquid, supercritical and/or near-supercritical carbon dioxide. It should be appreciated that solvents, co-solvents and/or surfactants can be contained in the carbon dioxide.

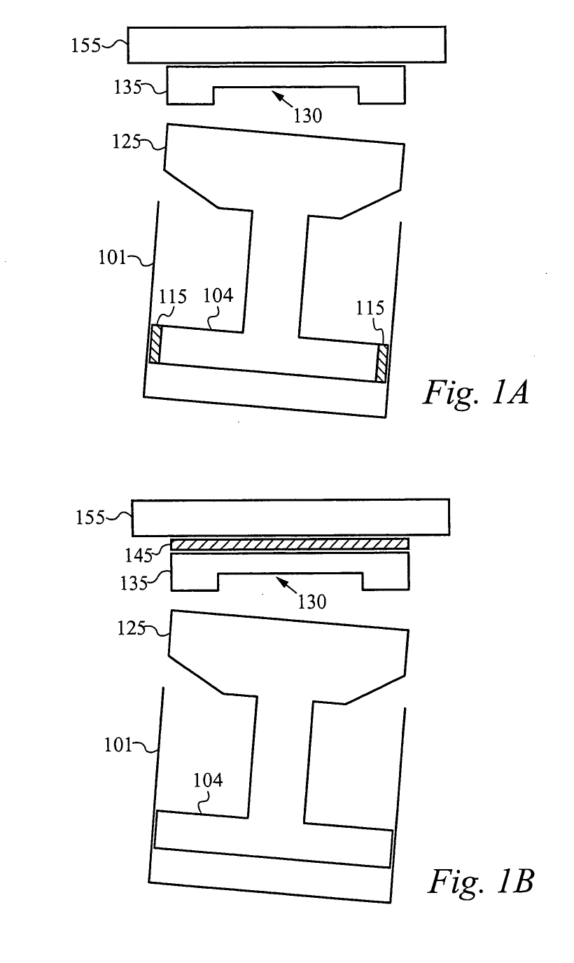

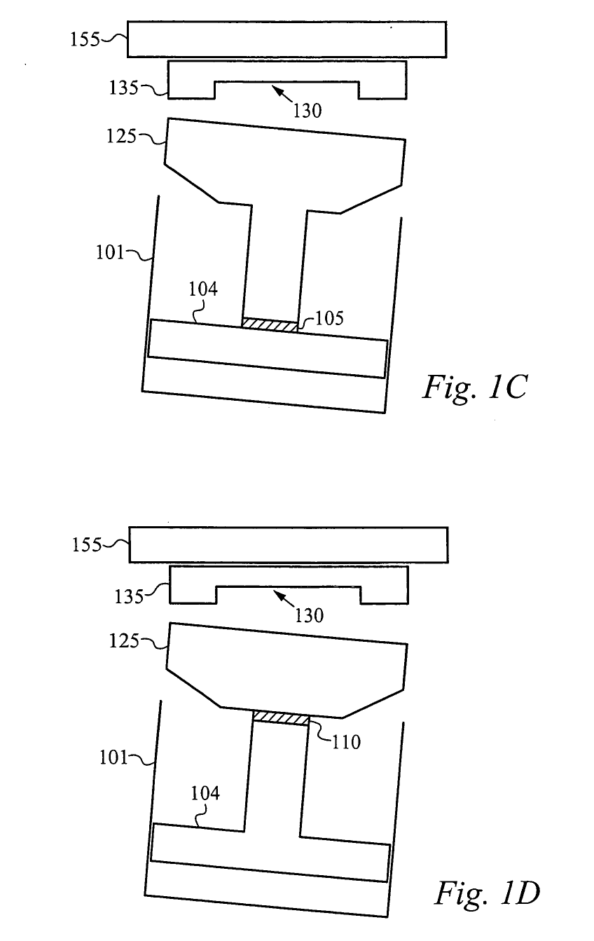

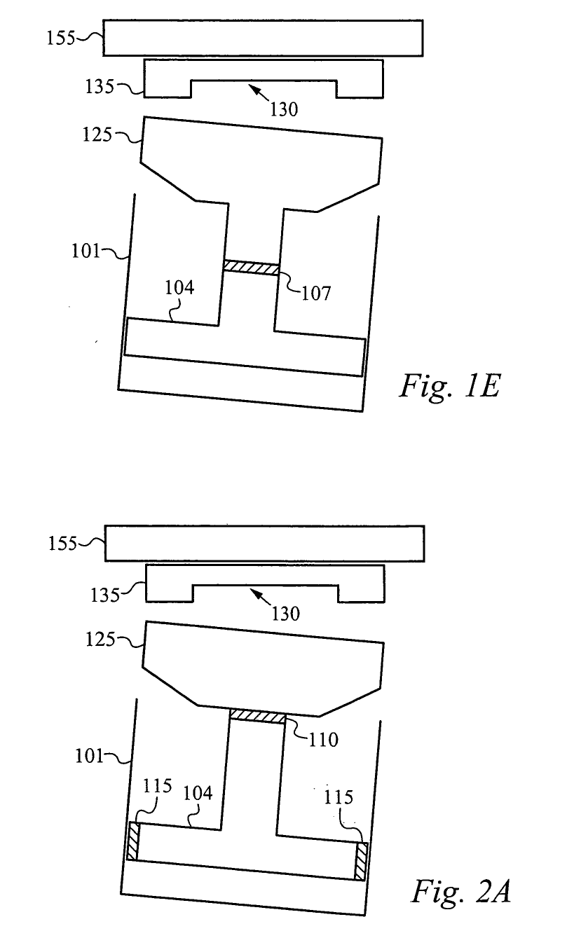

FIGS. 1A to 1E are schematic illustrations of an apparatus for closing a chamber, including deforming means and showing a cavity in the first chamber housing, in accordance with embodiments of the present invention. As shown in FIGS. 1A to 1E, an apparatus for closing a chamber includes a first chamber housing 135 and a second chamber housing 125. In the preferred embodiment of the invention, an apparatus for closing a chamber includes a means for forming a chamber, including a means for bringing the first chamber housing 135 into contact with the second chamber housing 125. In certain embodiments, the second chamber housing 125 is driven by a motivating structure for moving the second chamber housing 125 in and out of contact with the first chamber housing 135. Any means for powering the motivating structure should be suitable for implementing the present invention, such as a pneumatic source, a hydraulic source, a turbine, and a motor. To bring the first chamber housing 135 into contact with the second chamber housing 125, either one or both housing members move toward the other. According to the preferred embodiment, the second chamber housing 125 moves toward the first chamber housing 135. To that end, the second chamber housing 125 is coupled to a moveable member 104. Preferably, the moveable member 104 is a piston mounted within a casing 101. Preferably, the moveable member 104 is reciprocable along an axis between a first position and a second position, such that the second chamber housing 125 contacts the first chamber housing 135 while the moveable member 104 is in the first position, and such that the second chamber housing 125 is not in contact with the first chamber housing 135 while the moveable member 104 is in the second position. It should be appreciated that various different motivating structure configurations can be made for driving the second chamber housing 125 to move it in and out of contact with the first chamber housing 135 without departing from the spirit and scope of the invention. When the first chamber housing 135 is pressed into intimate contact with the second chamber housing 125 any misalignment will cause the formation of undesirable particles or contamination.

In the preferred embodiment, the apparatus for closing a chamber includes a deforming means 115 for preventing formation of particles while the first chamber 135 housing contacts the second chamber housing 125. Preferably, the deforming means 115 deforms to accommodate any misalignment while the means for forming a chamber operates. As FIG. 1B depicts, in one embodiment of the invention, a deforming means 145 is mounted to the first chamber housing 135. As shown in FIGS. 1C, 1D, and 1E, in certain embodiments, a deforming means 105, 110, and 107, respectively, is mounted in the second chamber housing 125.

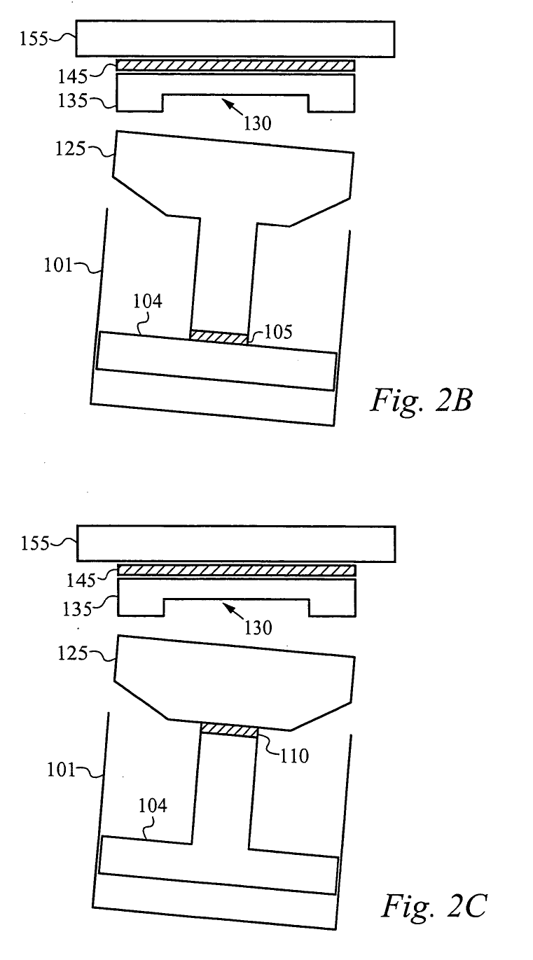

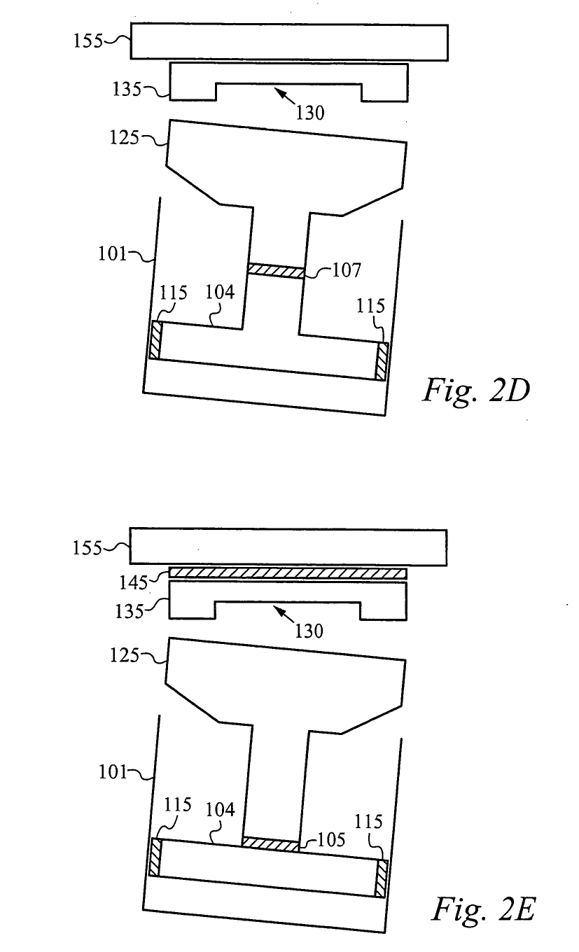

FIGS. 2A to 2E are schematic illustrations of alternative embodiments of an apparatus for closing a chamber, showing various combinations of the deforming means separately shown in FIGS. 1A to 1E, of which:

FIG. 2A shows a deforming means 115, 110, corresponding to the deforming means separately shown in FIGS. 1A and 1D.

FIG. 2B depicts a deforming means 145, 105, corresponding to the deforming means separately shown in FIGS. 1B and 1C.

FIG. 2C shows a deforming means 145, 110, corresponding to the deforming means separately illustrated in FIGS. 1B and 1D.

FIG. 2D shows a deforming means 115, 107, corresponding to the deforming means separately illustrated in FIGS. 1A and 1E.

FIG. 2E illustrates a deforming means 115, 145, 105, corresponding to the deforming means separately shown in FIGS. 1A, 1B and 1C.

It should be appreciated that while the invention contemplates the use of the deforming means illustrated in FIGS. 1A to 1E and FIGS. 2A to 2E, various different deforming means configurations can be made without departing from the spirit and scope of the invention.

As illustrated in FIGS. 1A to 1E and FIGS. 2A to 2E, in certain embodiments of the invention, the first chamber housing 135 includes a first interior surface defining a first cavity 130. Preferably, the first interior surface defining a first cavity 130 is sized to contain a semiconductor wafer for forming integrated circuits. In certain embodiments, the first chamber housing 135 is mounted to a structure 155 for stabilizing the first chamber housing 135 while the first chamber housing 135 contacts the second chamber housing 125.

In one embodiment of the invention, an apparatus for closing a chamber includes a deforming means comprising a material 115 between a surface of the moveable member 104 and a surface of the casing 101 shown in FIG. 1A. In one embodiment, a deforming means comprises a material 145 positioned between a surface of the first chamber housing 135 and a surface of the structure 155 to which the first chamber housing 135 is mounted shown in FIG. 1B. As illustrated in FIG. 1C, in one embodiment of the invention, a deforming means comprises a material 105 between a surface of the second chamber housing 125 and a surface of the motivating structure 104. Preferably, the material is an abrasion resistant material characterized by high impact strength and having a low coefficient of friction. In preferred embodiments of the invention, the material comprises polyether ether ketone (PEEK™), thermoplastic resin, polyolefin type resin, polyamide resin, polyester resin, polyether resin, polynitrile resin, polymethacrylate resin, polyvinyl resin, cellulose resin, fluorine resin and a composition of PEEK™ and resins and/or fillers.

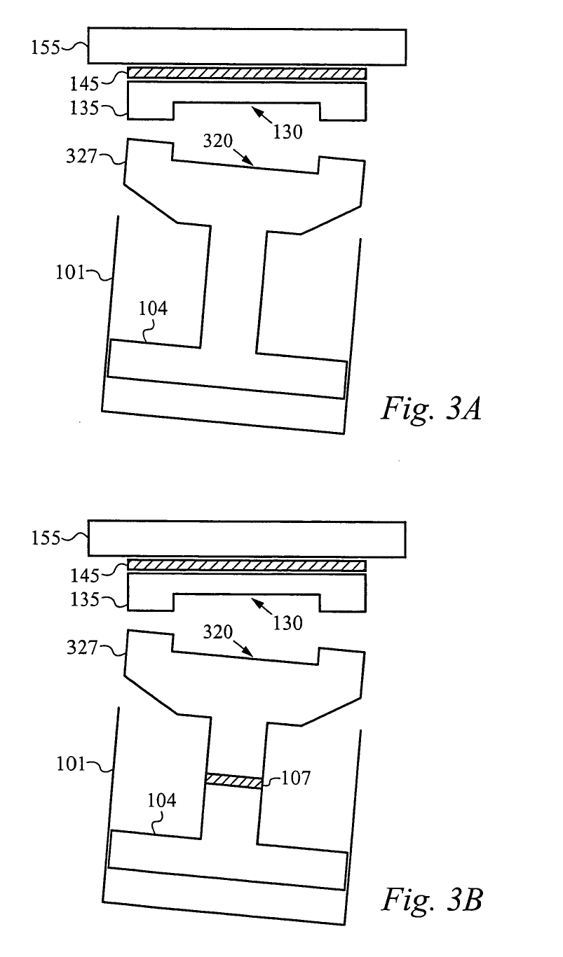

FIGS. 3A to 3B are schematic illustrations of an apparatus for closing a chamber, including various configurations of deforming means and showing a cavity in the second chamber housing, in accordance with embodiments of the present invention. In certain embodiments of the invention, the second chamber housing 327 includes a second interior surface defining a second cavity 320 shown in FIGS. 3A to 3B. Preferably, the second interior surface defining a second cavity 320 is sized such that when juxtaposed with the first cavity 130 a region thereby formed is sufficiently sized to contain a semiconductor wafer.

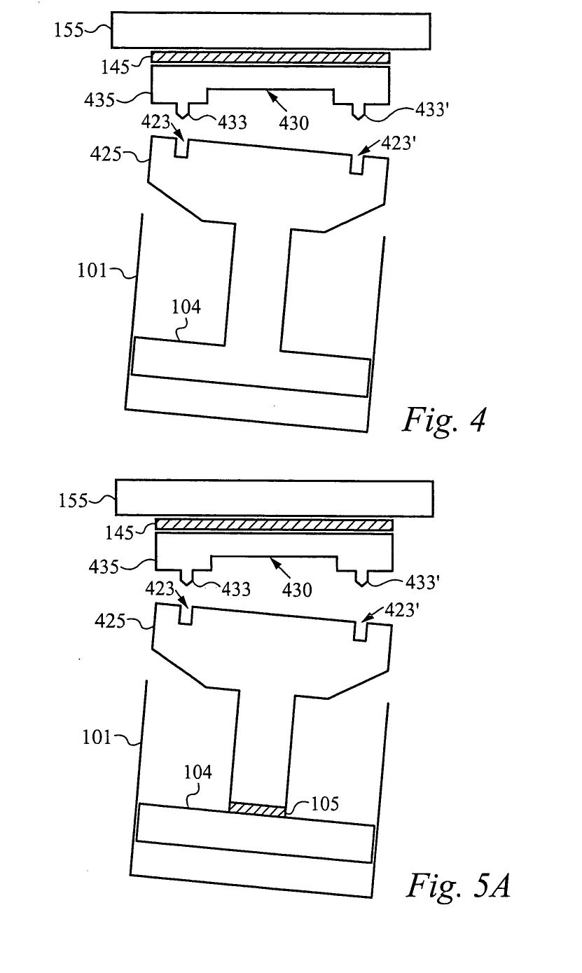

FIG. 4 is a schematic illustration of an apparatus for closing a chamber, including deforming means and showing an alignment means, in accordance with one embodiment of the present invention. As FIG. 4 depicts, in certain embodiments of the invention, an apparatus for closing a chamber includes an alignment means 433, 423, 433′, 423′ for reducing an amplitude of relative motion between the first chamber housing 435 and the second chamber housing 425 while the first chamber housing 435 contacts the second chamber housing 425.

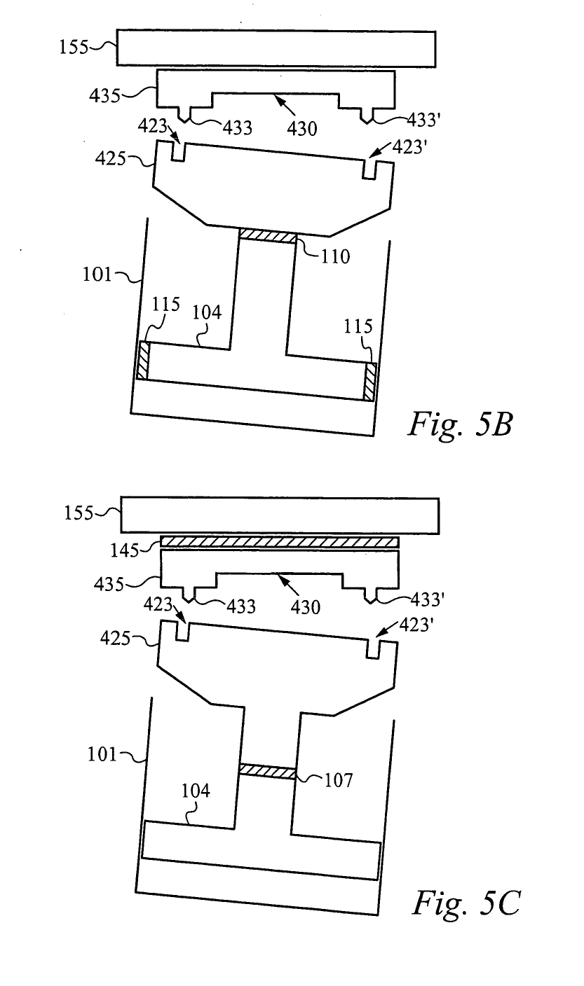

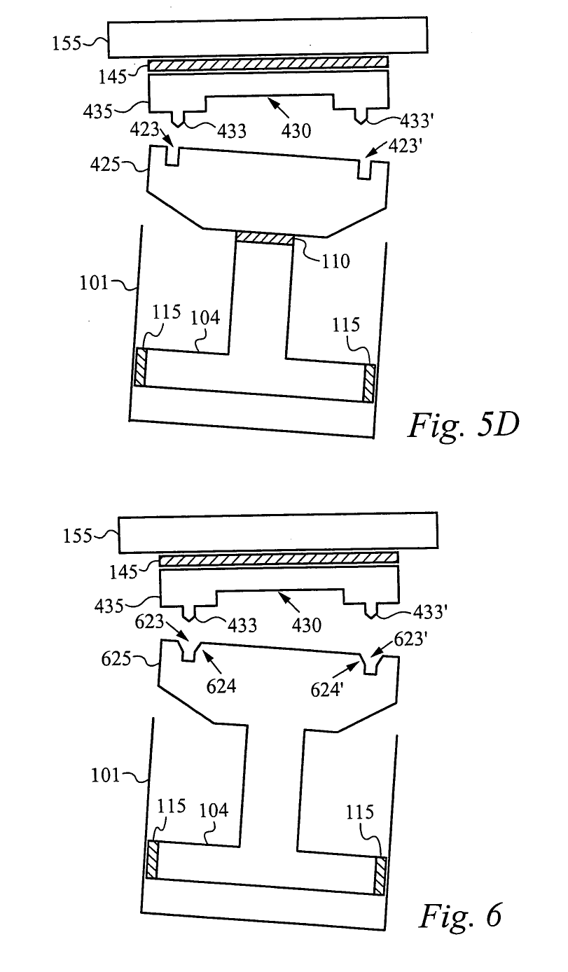

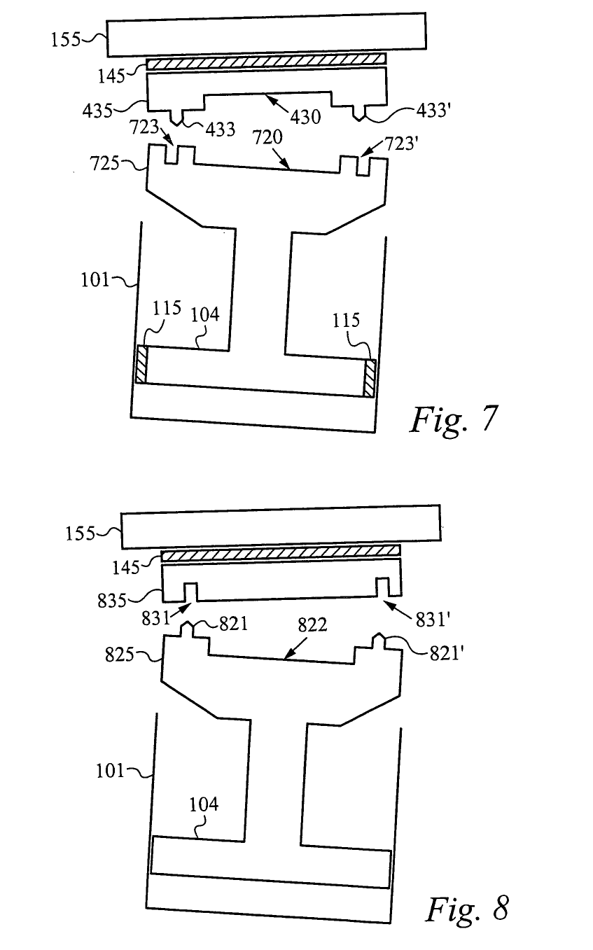

FIGS. 5A to 5D are schematic illustrations of an apparatus for closing a chamber, including an alignment means and showing various configurations of deforming means, in accordance with embodiments of the present invention. As shown in FIG. 4 and FIGS. 5A to 5D, in certain embodiments, the alignment means comprises a first chamber housing feature 433, 433′ adapted to engage with a second chamber housing feature 423, 423′, respectively, to particularly position the second chamber housing 425 relative to the first chamber housing 435 as contact is made. In certain embodiments, the first chamber housing feature and/or the second chamber housing feature comprises a protrudance. Preferably, the protrudance has a particularly shaped outer edge adapted to interfit with a recess defined in the first chamber housing and/or the second chamber housing. As illustrated in FIG. 4 and FIGS. 5A to 5D, in certain embodiments of the invention, the alignment means comprises a pin-like structure 433, 433′ located on the first chamber housing 435. In certain embodiments, an aperture 423, 423′ is defined in the second chamber housing 425 to securely receive the pin-like structure 433, 433′.

FIG. 8 is a schematic illustration of one embodiment of an apparatus for closing a chamber, including deforming means and a cavity in the second chamber housing 825, showing an alternative alignment means. As FIG. 8 depicts, in one embodiment, an alignment means comprises two pin-like structures 821, 821′ located on the second chamber housing 825. In one embodiment, two apertures 831, 881′ are defined in the first chamber housing 835 to securely receive the pin-like structures 821, 821′. It should be appreciated that while the invention contemplates the use of the pin-like structures and apertures illustrated in FIG. 4, FIGS. 5A to 5D, and FIG. 8, various pin-like structures and apertures can be located on the first chamber housing and/or the second chamber housing without departing from the spirit and scope of the invention. Alternatively, the aperture can comprise a groove and the protrudance a corresponding ridge.

FIG. 6 is a schematic illustration of an apparatus for closing a chamber, including deforming means and an alternative alignment means, in accordance with one embodiment of the present invention. In one embodiment, an aperture 623, 623′, defined in the second chamber housing 625, is elongated in shape and has at least one chamfered inner wall 624, 624′ adapted to facilitate alignment of the aperture 623, 623′ with a pin-like structure 433, 433′.

In certain embodiments of the invention, an apparatus for closing a chamber includes a first chamber housing including a manifold having thereon a plurality of fluid outlets for distributing a process fluid. In certain embodiments, an apparatus for closing a chamber includes a second chamber housing including a manifold having thereon a plurality of fluid outlets for distributing a process fluid. Preferably, the fluid comprises gaseous, liquid, supercritical and/or near-supercritical carbon dioxide. In certain embodiments, solvents, co-solvents and/or surfactants are contained in the carbon dioxide

In certain embodiments, an apparatus for closing a chamber includes means for performing a supercritical process. Preferably, the means for performing a supercritical process includes a means for circulating at least one of gaseous, liquid, supercritical and near-supercritical carbon dioxide in the chamber.

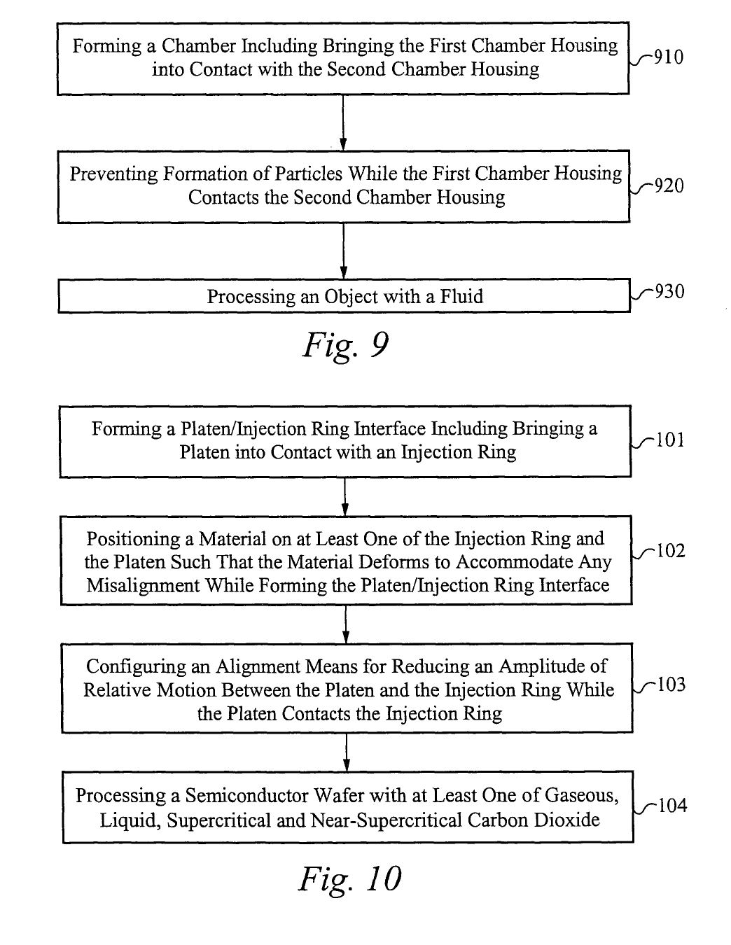

FIG. 9 is a flow chart showing a method of closing a chamber, the chamber having a first chamber housing and a second chamber housing, in accordance with embodiments of the present invention. In step 910, a chamber is formed by bringing the first chamber housing into contact with the second chamber housing. In certain embodiments, step 910 comprises moving the second chamber housing in and out of contact with the first chamber housing. In step 920, the formation of particles is prevented while the first chamber housing contacts the second chamber housing.

In certain embodiments, step 920 comprises positioning a material on at least one of the first chamber housing and the second chamber housing such that the material deforms to accommodate any misalignment while forming a chamber. Preferably, the material comprises an abrasion resistant material characterized by high impact strength and having a low coefficient of friction. In certain embodiments, the material comprises at least one of polyether ether ketone (PEEK™), thermoplastic resin, polyolefin type resin, polyamide resin, polyester resin, polyether resin, polynitrile resin, polymethacrylate resin, polyvinyl resin, cellulose resin, fluorine resin and a composition of PEEK™ and at least one of resins and fillers. In certain embodiments, step 920 comprises employing an alignment means for reducing an amplitude of relative motion between the first chamber housing and the second chamber housing while the first chamber housing contacts the second chamber housing. In certain embodiments, configuring an alignment means comprises configuring a first-chamber-housing feature to engage with a second-chamber-housing feature to particularly position the second chamber while the first chamber housing contacts the second chamber housing. In an optional step 930, an object is processed with a fluid. In one embodiment, the object is a semiconductor wafer for forming integrated circuits and the fluid comprises a gaseous, liquid, supercritical and/or near-supercritical carbon dioxide.

FIG. 10 is a flow chart showing a method of eliminating particle generation at a platen/injection ring interface in accordance with embodiments of the present invention. In step 101, a platen/injection ring interface is formed, wherein a platen is brought into contact with an injection ring. In step 102, a material is positioned on at least one of the injection ring and the platen such that the material deforms to accommodate any misalignment while forming the platen/injection ring interface. One embodiment of a method of eliminating particle generation at a platen/injection ring interface, in accordance the present invention, includes step 103 shown in FIG. 10. In step 103, an alignment means is configured for reducing an amplitude of relative motion between the platen and the injection ring while the platen contacts the injection ring. In an optional step 104, a semiconductor wafer is processed with at least one of gaseous, liquid, supercritical and near-supercritical carbon dioxide.

While the processes and apparatus of this invention have been described in detail for the purpose of illustration, the inventive processes and apparatus are not to be construed as limited thereby. It will be readily apparent to those of reasonable skill in the art that various modifications to the foregoing preferred embodiments can be made without departing from the spirit and scope of the invention as defined by the appended claims.

1. An apparatus for closing a chamber, the chamber having a first chamber housing and a second chamber housing, comprising:
means for forming a chamber including means for bringing the first chamber housing into contact with the second chamber housing; and
deforming means for preventing formation of particles while the first chamber housing contacts the second chamber housing, wherein the deforming means is mounted on at least one of the first chamber housing and the second chamber housing such that it deforms to accommodate any misalignment while the means for forming a chamber operates.

2. The apparatus of claim 1 wherein the first chamber housing includes a first interior surface defining a first cavity.

3. The apparatus of claim 2 wherein the first interior surface defining a first cavity is sized to contain a semiconductor wafer for forming integrated circuits.

4. The apparatus of claim 2 wherein the second chamber housing includes a second interior surface defining a second cavity.

5. The apparatus of claim 4 wherein the second interior surface defining a second cavity is sized such that when juxtaposed with the first cavity a region thereby formed is sufficiently sized to contain a semiconductor wafer for forming integrated circuits.

6. The apparatus of claim 1 wherein the first chamber housing is mounted to a structure for stabilizing the first chamber housing while the first chamber housing contacts the second chamber housing.

7. The apparatus of claim 6 wherein the second chamber housing is driven by a motivating structure, being constructed and arranged to move the second chamber housing in and out of contact with the first chamber housing.

8. The apparatus of claim 7 wherein the motivating structure is powered by at least one of a pneumatic source, a hydraulic source, a turbine, and a motor.

9. The apparatus of claim 7 wherein the motivating structure comprises:
a body defining a casing; and
a moveable member, being positioned in the casing and being reciprocable along an axis between a first position and a second position, wherein the second chamber housing contacts the first chamber housing while the moveable member is in the first position, and wherein the second chamber housing is not in contact with the first chamber housing while the moveable member is in the second position.

10. The apparatus of claim 9 wherein the deforming means comprises at least one of a material between a surface of the first chamber housing and a surface of the structure to which the first chamber housing is mounted, a material between a surface of the second chamber housing and a surface of the motivating structure, and a material between a surface of the moveable member and a surface of the casing.

11. The apparatus of claim 10 wherein the material comprises an abrasion resistant material characterized by high impact strength and having a low coefficient of friction.

12. The apparatus of claim 10 wherein the material comprises at least one of polyether ether ketone (PEEK™), thermoplastic resin, polyolefin type resin, polyamide resin, polyester resin, polyether resin, polynitrile resin, polymethacrylate resin, polyvinyl resin, cellulose resin, fluorine resin and a composition of PEEK™ and at least one of resins and fillers.

13. The apparatus of claim 1 further comprising alignment means for reducing an amplitude of relative motion between the first chamber housing and the second chamber housing while the first chamber housing contacts the second chamber housing.

14. The apparatus of claim 13 wherein the alignment means comprises a first chamber housing feature adapted to engage with a second chamber housing feature to particularly position the second chamber while the first chamber housing contacts the second chamber housing.

15. The apparatus of claim 14 wherein at least one of the first chamber housing feature and the second chamber housing feature comprises a protrudance, wherein the protrudance has a particularly shaped outer edge adapted to interfit with a recess defined in at least one of the first chamber housing and the second chamber housing.

16. The apparatus of claim 13 wherein the alignment means comprises a pin-like structure located on at least one of the first chamber housing and the second chamber housing and an aperture defined in at least one of the first chamber housing and the second chamber housing to securely receive the pin-like structure.

17. The apparatus of claim 16 wherein the aperture is elongated in shape and has at least one chamfered inner wall adapted to facilitate alignment of the aperture with the pin-like structure.

18. The apparatus of claim 1 wherein at least one of the first chamber housing and the second chamber housing comprises a manifold having thereon a plurality of fluid outlets for distributing a process fluid.

19. The apparatus of claim 1 further comprising means for performing a supercritical process.

20. The apparatus of claim 19 wherein the means for performing a supercritical process comprises means for circulating at least one of gaseous, liquid, supercritical and near-supercritical carbon dioxide in the chamber.

21. A method of closing a chamber, the chamber having a first chamber housing and a second chamber housing, comprising the steps of:
a. forming a chamber including bringing the first chamber housing into contact with the second chamber housing; and
b. preventing formation of particles while the first chamber housing contacts the second chamber housing.

22. The method of claim 21 wherein the step of forming a chamber comprises moving the second chamber housing in and out of contact with the first chamber housing.

23. The method of claim 21 wherein the step of preventing formation of particles comprises positioning a material on at least one of the first chamber housing and the second chamber housing such that the material deforms to accommodate any misalignment while forming a chamber.

24. The method of claim 23 wherein the material comprises an abrasion resistant material characterized by high impact strength and having a low coefficient of friction.

25. The method of claim 23 wherein the material comprises at least one of polyether ether ketone (PEEK™), thermoplastic resin, polyolefin type resin, polyamide resin, polyester resin, polyether resin, polynitrile resin, polymethacrylate resin, polyvinyl resin, cellulose resin, fluorine resin and a composition of PEEK™ and at least one of resins and fillers.

26. The method of claim 21 wherein the step of preventing formation of particles comprises configuring an alignment means for reducing an amplitude of relative motion between the first chamber housing and the second chamber housing while the first chamber housing contacts the second chamber housing.

27. The method of claim 26 wherein the step of employing an alignment means comprises configuring a first-chamber-housing feature to engage with a second-chamber-housing feature to particularly position the second chamber while the first chamber housing contacts the second chamber housing.

28. The method of claim 21 further comprising processing an object with a fluid.

29. The method of claim 28 wherein the step of processing an object with a fluid comprises processing a semiconductor wafer with at least one of gaseous, liquid, supercritical and near-supercritical carbon dioxide.

30. A method of eliminating particle generation at a platen/injection ring interface, comprising the steps of:
a. forming a platen/injection ring interface including bringing a platen into contact with an injection ring; and
b. positioning a material on at least one of the injection ring and the platen such that the material deforms to accommodate any misalignment while forming the platen/injection ring interface.

31. A method of 30 further comprising the step of configuring an alignment means for reducing an amplitude of relative motion between the platen and the injection ring while the platen contacts the injection ring.

32. The method of claim 30 further comprising the step of processing a semiconductor wafer with at least one of gaseous, liquid, supercritical and near-supercritical carbon dioxide.
